(19) United States
(12) Patent Application Publication
(10) Pub. No.: US 2025/0295015 A1
(43) Pub. Date: Sep. 18, 2025

(54) OPTICAL DEVICE AND OPTICAL METHOD

(71) Applicant: HTC Corporation, Taoyuan City (TW)

(72) Inventors: Chun-Yih WU, Taoyuan City (TW); Ta-Chun PU, Taoyuan City (TW); Yen-Liang KUO, Taoyuan City (TW)

(73) Assignee: HTC Corporation, Taoyuan City (TW)

(21) Appl. No.: 19/048,021

(22) Filed: Feb. 7, 2025

Related U.S. Application Data
(60) Provisional application No. 63/565,724, filed on Mar. 15, 2024.

(30) Foreign Application Priority Data
Jan. 15, 2025 (TW) 114101593

(51) Int. Cl. H10K 59/80; G02B 1/00; G06F 3/01; H04N 25/70; H10K 59/65; H10N 30/20; H10N 30/80

(52) U.S. Cl. CPC H10K 59/879; G02B 1/002; H10K 59/65; H10N 30/20; H10N 30/802; G06F 3/013; H04N 25/70

(57) ABSTRACT

An optical device includes a metamaterial lens layer, an OLED (Organic Light-Emitting Diode) layer, an imager element, and a substrate. The OLED layer is adjacent to the metamaterial lens layer. The substrate is configured to carry the imager element. When a visible light is transmitted through the metamaterial lens layer and the OLED layer to the imager element, the imager element generates an image signal.

### CROSS REFERENCE TO RELATED APPLICATIONS

This application claims the benefit of U.S. Provisional Application No. 63/565,724, filed on Mar. 15, 2024, and also claims priority of Taiwan Patent Application No. 114101593, filed on Jan. 15, 2025, the entirety of which are incorporated by reference herein.

### BACKGROUND OF THE INVENTION

### Field of the Invention

The invention relates in general to an optical device, and more particularly, it relates to an optical device for use in the field of photographic technology.

### Description of the Related Art

In the technology used to design cameras, there must often be a trade-off between refractive index and dispersion when dealing with conventional optical materials. However, an optical material with a low refractive index also tends to limit the performance and design flexibility of the optical device in question. Accordingly, there is a need to propose a novel solution for solving this problem of the prior art.

### BRIEF SUMMARY OF THE INVENTION

In an exemplary embodiment, the invention is directed to an optical device that includes a metamaterial lens layer, an OLED (Organic Light-Emitting Diode) layer, an imager element, and a substrate. The OLED layer is adjacent to the metamaterial lens layer. The substrate is configured to carry the imager element. When a visible light is transmitted through the metamaterial lens layer and the OLED layer to the imager element, the imager element generates an image signal.

In some embodiments, the metamaterial lens layer is disposed on the OLED layer.

In some embodiments, the OLED layer is disposed on the metamaterial lens layer.

In some embodiments, the operational frequency of the optical device is from 120 THz to 790 THz.

In some embodiments, the thickness of the metamaterial lens layer is from 0.1 to 1 wavelength of the operational frequency.

In some embodiments, the optical device further includes a piezoelectric layer positioned between the metamaterial lens layer and the OLED layer.

In some embodiments, the piezoelectric layer is made of a lithium niobate material or a lithium tantalate material.

In some embodiments, the metamaterial lens layer, the OLED layer and the piezoelectric layer are adjacent to each other, or are combined by using the technology of heterogeneous photonics chip.

In some embodiments, the optical device further includes a controller for generating a control voltage. The control voltage is applied to the piezoelectric layer.

In some embodiments, the shape of the piezoelectric layer is changed according to the control voltage.

In some embodiments, the thickness of the piezoelectric layer is from 0.1 to 1 wavelength of the operational frequency.

In some embodiments, the metamaterial lens layer is disposed on the piezoelectric layer, and the piezoelectric layer is disposed on the OLED layer.

In some embodiments, the distance between the OLED layer and the imager element is from 0.125 to 10 wavelengths of the operational frequency.

In some embodiments, the OLED layer is disposed on the piezoelectric layer, and the piezoelectric layer is disposed on the metamaterial lens layer.

In some embodiments, the distance between the metamaterial lens layer and the imager element is from 0.125 to 10 wavelengths of the operational frequency.

In some embodiments, the optical device further includes an infrared light source and a mirror element. The infrared light source transmits an incident light to an eyeball. The mirror element receives a first reflection light from the eyeball, and generates a second reflection light according to the first reflection light. The second reflection light is transmitted through the metamaterial lens layer and the OLED layer to the imager element.

In some embodiments, the optical device supports an eye-tracking function.

In another exemplary embodiment, the invention is directed to an optical method that includes the steps of: providing a metamaterial lens layer and an OLED layer, wherein the OLED layer is adjacent to the metamaterial lens layer; transmitting a visible light through the metamaterial lens layer and the OLED layer to an imager element, wherein the imager element is carried by a substrate; and generating the image signal by an imager element.

In some embodiments, the optical method further includes the step of providing a piezoelectric layer. The piezoelectric layer is positioned between the metamaterial lens layer and the OLED layer.

In some embodiments, the optical method further includes the step of applying a control voltage to the piezoelectric layer. The shape of the piezoelectric layer is changed according to the control voltage.

### BRIEF DESCRIPTION OF DRAWINGS

The invention can be more fully understood by reading the subsequent detailed description and examples with references made to the accompanying drawings, wherein:

FIG. 1 is a sectional view of an optical device according to an embodiment of the invention;

FIG. 2 is a sectional view of an optical device according to an embodiment of the invention;

FIG. 3 is a sectional view of an optical device according to an embodiment of the invention;

FIG. 4 is a sectional view of an optical device according to an embodiment of the invention;

FIG. 5 is a sectional view of an optical device according to an embodiment of the invention; and

FIG. 6 is a flowchart of an optical method according to an embodiment of the invention.

### DETAILED DESCRIPTION OF THE INVENTION

In order to illustrate the foregoing and other purposes, features and advantages of the invention, the embodiments and figures of the invention will be described in detail as follows.

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. The term “substantially” means the value is within an acceptable error range. One skilled in the art can solve the technical problem within a predetermined error range and achieve the proposed technical performance. Also, the term “couple” is intended to mean either an indirect or direct electrical connection. Accordingly, if one device is coupled to another device, that connection may be through a direct electrical connection, or through an indirect electrical connection via other devices and connections.

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

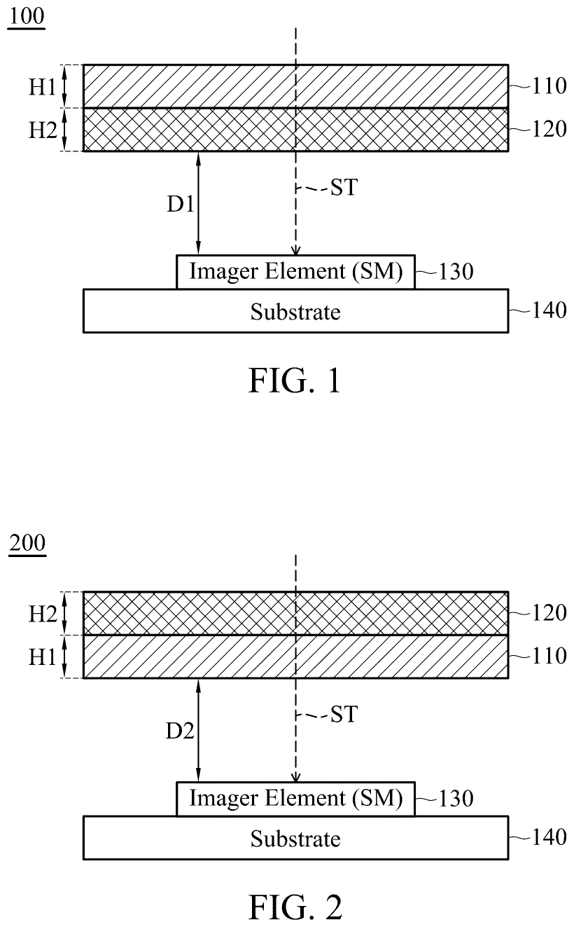

FIG. 1 is a sectional view of an optical device 100 according to an embodiment of the invention. The optical device 100 may be applied in a mobile device, such as a smart phone, a tablet computer, or a notebook computer. In the embodiment of FIG. 1, the optical device 100 includes a metamaterial lens layer 110, an OLED (Organic Light-Emitting Diode) layer 120, an imager element 130, and a substrate 140. It should be understood that the optical device 100 may further include other components, such as a processor, a battery element, and/or a housing, although they are not displayed in FIG. 1.

The metamaterial lens layer 110 has a periodical structure, and its shape and type are not limited in the invention. The OLED layer 120 is adjacent to the metamaterial lens layer 110. For example, the OLED layer 120 may include a plurality of OLED units (not shown). It should be noted that the term “adjacent” or “close” over the disclosure means that the distance (spacing) between two corresponding elements is smaller than a predetermined distance (e.g., 10 mm or the shorter), or means that the two corresponding elements directly touch each other (i.e., the aforementioned distance/spacing between them is reduced to 0). In some embodiments, the metamaterial lens layer 110 is disposed on the OLED layer 120, and they are directly attached to each other.

For example, the imager element 130 may include an array composed of multiple CCDs (Charge-Coupled Devices) (not shown). Alternatively, the imager element 130 may be a CMOS (Complementary Metal-Oxide-Semiconductor) sensor, but it is not limited thereto. The substrate 140 is configured to carry the imager element 130. Generally, when a visible light ST is transmitted through the metamaterial lens layer 110 and the OLED layer 120 to the imager element 130, the imager element 130 can generate an image signal SM according to the visible light ST. In some embodiments, the optical device 100 provides a camera function. According to practical measurements, the metamaterial lens layer 110 has a sufficient equivalent refractive index for fine-tuning the direction and phase of the visible light ST. The overall size of the optical device 100 using the metamaterial lens layer 110 can be significantly reduced due to the metamaterial lens layer 110's characteristics of thinness and lightness. In addition, since the metamaterial lens layer 110 is well integrated with the OLED layer 120, the optical device 100 can be used as an under-screen camera element.

In some embodiments, the operational frequency of the optical device 100 is from 120 THz to 790 THz. Furthermore, the frequency of the visible light ST also falls within the aforementioned range of the operational frequency of the optical device 100.

In some embodiments, the element sizes and element parameters of the optical device 100 will be described as follows. The thickness H1 of the metamaterial lens layer 110 may be from 0.1 to 1 wavelength (λ/10˜ 1λ) of the operational frequency of the optical device 100. The distance D1 between the OLED layer 120 and the imager element 130 may be from 0.125 to 10 wavelengths (λ/8˜10λ) of the operational frequency of the optical device 100. The above ranges of element sizes and element parameters are calculated and obtained according to many experimental results, and they help to maximize the equivalent refractive index of the optical device 100 and also to minimize the overall size of the optical device 100.

The following embodiments will introduce different configurations and detail structural features of the optical device 100. It should be understood that these figures and descriptions are merely exemplary, rather than limitations of the invention.

FIG. 2 is a sectional view of an optical device 200 according to an embodiment of the invention. FIG. 2 is similar to FIG. 1. In the embodiment of FIG. 2, the position of the metamaterial lens layer 110 is exchanged with that of the OLED layer 120. That is, the OLED layer 120 is disposed on the metamaterial lens layer 110. In addition, the distance D2 between the metamaterial lens layer 110 and the imager element 130 may be from 0.125 to 10 wavelengths (λ/8˜ 10λ) of the operational frequency of the optical device 200. According to practical measurements, such an exchanging design does not negatively affect the performance of the optical device 200, thereby increasing the design flexibility of the optical device 200. Other features of the optical device 200 of FIG. 2 are similar to those of the optical device 100 of FIG. 1. Accordingly, the two embodiments can achieve similar levels of performance.

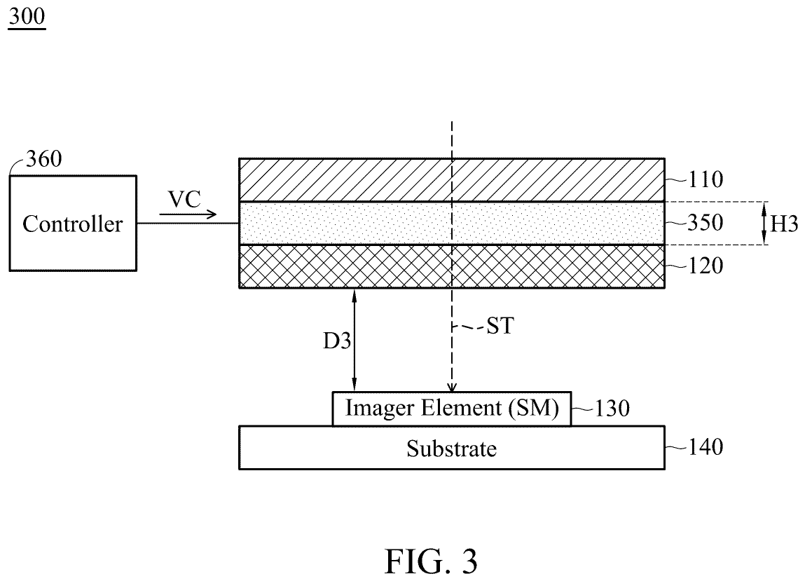

FIG. 3 is a sectional view of an optical device 300 according to an embodiment of the invention. FIG. 3 is similar to FIG. 1. In the embodiment of FIG. 3, the optical device 300 further includes a piezoelectric layer 350 and a controller 360. For example, the piezoelectric layer 350 may be made of a lithium niobate (LiNbO₃) material or a lithium tantalate (LiTaO₃) material, but it is not limited thereto. The piezoelectric layer 350 is positioned between the metamaterial lens layer 110 and the OLED layer 120. That is, the metamaterial lens layer 110 is disposed on the piezoelectric layer 350, and the piezoelectric layer 350 is disposed on the OLED layer 120. The metamaterial lens layer 110, the OLED layer 120 and the piezoelectric layer 350 may be adjacent to each other, or may be combined by using the technology of heterogeneous photonics chip. For example, the aforementioned technology of heterogeneous photonics chip may include a bonding technology, a heteroepitaxy technology, or a 3D (Three-Dimensional) stacking technology, but it is not limited thereto. The controller 360 generates a control voltage VC. The control voltage VC is applied to the piezoelectric layer 350. For example, the control voltage VC may be a DC (Direct Current) voltage or an AC (Alternating Current) voltage. It should be noted that the direction and phase of the visible light ST can be further adjusted since the shape of the piezoelectric layer 350 is changed according to the control voltage VC. In some embodiments, the thickness H3 of the piezoelectric layer 350 is from 0.1 to 1 wavelength (λ/10˜ 1λ) of the operational frequency of the optical device 300, and the distance D3 between the OLED layer 120 and the imager element 130 is from 0.125 to 10 wavelengths (λ/8˜ 10λ) of the operational frequency of the optical device 300. For example, the aforementioned thickness H3 may be from 500 nm to 2 μm. Other features of the optical device 300 of FIG. 3 are similar to those of the optical device 100 of FIG. 1. Accordingly, the two embodiments can achieve similar levels of performance.

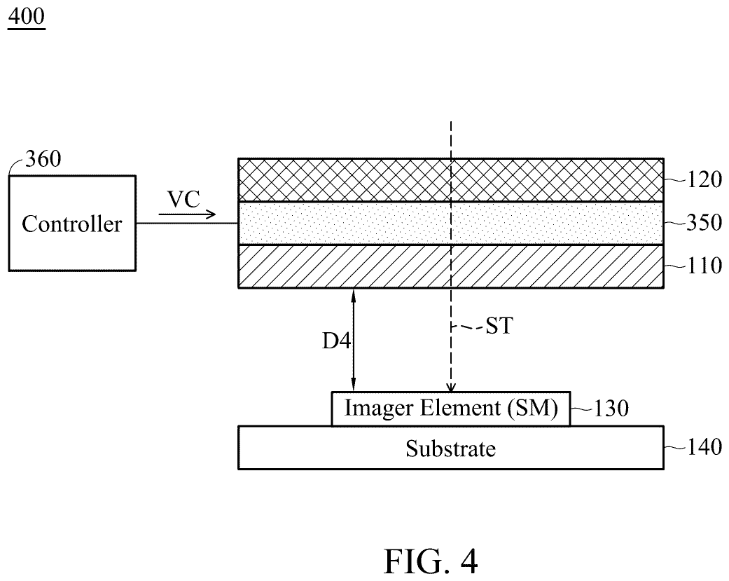

FIG. 4 is a sectional view of an optical device 400 according to an embodiment of the invention. FIG. 4 is similar to FIG. 3. In the embodiment of FIG. 4, the position of the metamaterial lens layer 110 is exchanged with that of the OLED layer 120. That is, the OLED layer 120 is disposed on the piezoelectric layer 350, and the piezoelectric layer 350 is disposed on the metamaterial lens layer 110. The metamaterial lens layer 110, the OLED layer 120 and the piezoelectric layer 350 may be adjacent to each other, or may be directly attached to each other. In some embodiments, the distance D4 between the metamaterial lens layer 110 and the imager element 130 may be from 0.125 to 10 wavelengths (λ/8˜ 10λ) of the operational frequency of the optical device 400. According to practical measurements, such an exchanging design does not negatively affect the performance of the optical device 400, thereby increasing the design flexibility of the optical device 400. Other features of the optical device 400 of FIG. 4 are similar to those of the optical device 300 of FIG. 3. Accordingly, the two embodiments can achieve similar levels of performance.

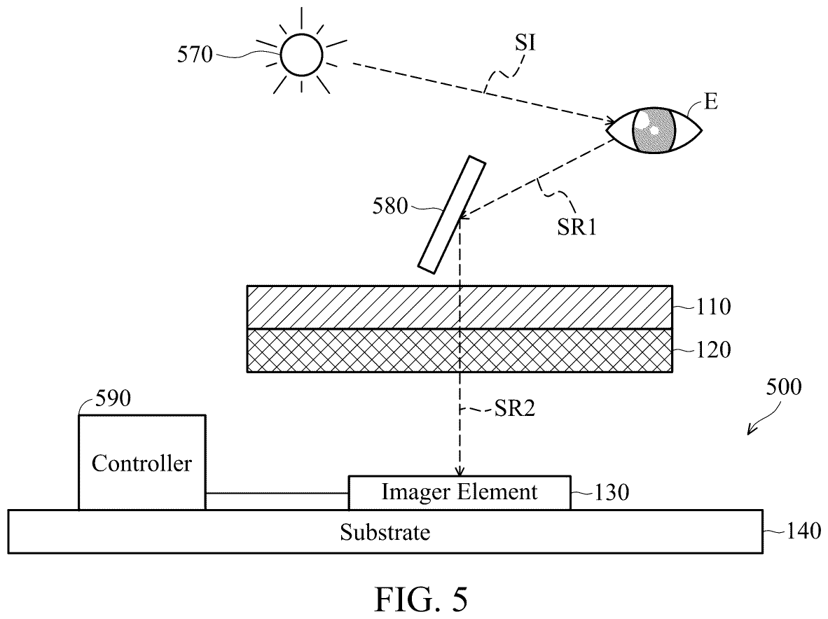

FIG. 5 is a sectional view of an optical device 500 according to an embodiment of the invention. FIG. 5 is similar to FIG. 1. In the embodiment of FIG. 5, the optical device 500 further includes an infrared light source 570, a mirror element 580, and a processor 590. The infrared light source 570 transmits an incident light SI to an eyeball E of a user. Next, the mirror element 580 receives a first reflection light SR1 from the eyeball E, and generates a second reflection light SR2 according to the first reflection light SR1. Then, the second reflection light SR2 is transmitted through the metamaterial lens layer 110 and the OLED layer 120 to the imager element 130. The processor 590 is disposed on the substrate 140, and is coupled to the imager element 130. The processor 590 can analyze the relative information of the second reflection light SR2, so as to estimate the movement or rotation of the eyeball E of the user. Thus, the optical device 500 can support an eye-tracking function. In alternative embodiments, the optical device 500 further includes a piezoelectric layer (not shown) positioned between the metamaterial lens layer 110 and the OLED layer 120. The position of the metamaterial lens layer 110 may be exchanged with that of the OLED layer 120. Other features of the optical device 500 of FIG. 5 are similar to those of the optical device 100 of FIG. 1. Accordingly, the two embodiments can achieve similar levels of performance.

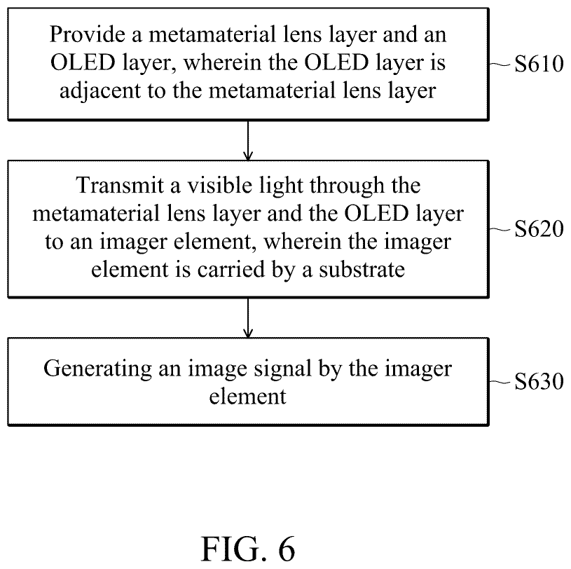

FIG. 6 is a flowchart of an optical method according to an embodiment of the invention. To begin, in step S610, a metamaterial lens layer and an OLED layer are provided. The OLED layer is adjacent to the metamaterial lens layer. In step S620, a visible light is transmitted through the metamaterial lens layer and the OLED layer to an imager element. The imager element is carried by a substrate. Finally, in step S630, an image signal is generated by the imager element. It should be understood that these steps are not required to be performed in order, and every feature of the embodiments of FIGS. 1-5 may be applied to the optical method of FIG. 6.

The invention proposed a novel optical device and a novel optical method. In comparison to the conventional design, the invention has at least the advantages of reducing the overall size, increasing the equivalent refractive index, and enhancing the integration and the design flexibility. Therefore, the invention is suitable for application in a variety of devices.

Note that the above element sizes and element parameters are not limitations of the invention. A designer can fine-tune these setting values according to different requirements. It should be understood that the optical device and the optical method of the invention are not limited to the configurations of FIGS. 1-6. The invention may include any one or more features of any one or more embodiments of FIGS. 1-6. In other words, not all of the features displayed in the figures should be implemented in the optical device and the optical method of the invention.

The method of the invention, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

It will be apparent to those skilled in the art that various modifications and variations can be made in the invention. It is intended that the standard and examples be considered as exemplary only, with a true scope of the disclosed embodiments being indicated by the following claims and their equivalents.

What is claimed is:

1. An optical device, comprising:
a metamaterial lens layer;
an OLED (Organic Light-Emitting Diode) layer, disposed adjacent to the metamaterial lens layer;
an imager element; and
a substrate, carrying the imager element;
wherein when a visible light is transmitted through the metamaterial lens layer and the OLED layer to the imager element, the imager element generates an image signal.

2. The optical device as claimed in claim 1, wherein the metamaterial lens layer is disposed on the OLED layer.

3. The optical device as claimed in claim 1, wherein the OLED layer is disposed on the metamaterial lens layer.

4. The optical device as claimed in claim 1, wherein an operational frequency of the optical device is from 120 THz to 790 THz.

5. The optical device as claimed in claim 4, wherein a thickness of the metamaterial lens layer is from 0.1 to 1 wavelength of the operational frequency.

6. The optical device as claimed in claim 4, further comprising:
a piezoelectric layer, positioned between the metamaterial lens layer and the OLED layer.

7. The optical device as claimed in claim 6, wherein the piezoelectric layer is made of a lithium niobate material or a lithium tantalate material.

8. The optical device as claimed in claim 6, wherein the metamaterial lens layer, the OLED layer and the piezoelectric layer are adjacent to each other, or are combined by using a technology of heterogeneous photonics chip.

9. The optical device as claimed in claim 6, further comprising:
a controller, generating a control voltage, wherein the control voltage is applied to the piezoelectric layer.

10. The optical device as claimed in claim 9, wherein a shape of the piezoelectric layer is changed according to the control voltage.

11. The optical device as claimed in claim 6, wherein a thickness of the piezoelectric layer is from 0.1 to 1 wavelength of the operational frequency.

12. The optical device as claimed in claim 6, wherein the metamaterial lens layer is disposed on the piezoelectric layer, and the piezoelectric layer is disposed on the OLED layer.

13. The optical device as claimed in claim 12, wherein a distance between the OLED layer and the imager element is from 0.125 to 10 wavelengths of the operational frequency.

14. The optical device as claimed in claim 6, wherein the OLED layer is disposed on the piezoelectric layer, and the piezoelectric layer is disposed on the metamaterial lens layer.

15. The optical device as claimed in claim 14, wherein a distance between the metamaterial lens layer and the imager element is from 0.125 to 10 wavelengths of the operational frequency.

16. The optical device as claimed in claim 1, further comprising:
an infrared light source, transmitting an incident light to an eyeball; and
a mirror element, receiving a first reflection light from the eyeball, and generating a second reflection light according to the first reflection light;
wherein the second reflection light is transmitted through the metamaterial lens layer and the OLED layer to the imager element.

17. The optical device as claimed in claim 16, wherein the optical device supports an eye-tracking function.

18. An optical method, comprising the steps of:
providing a metamaterial lens layer and an OLED layer, wherein the OLED layer is adjacent to the metamaterial lens layer;
transmitting a visible light through the metamaterial lens layer and the OLED layer to an imager element, wherein the imager element is carried by a substrate; and
generating an image signal by the imager element.

19. The optical method as claimed in claim 18, further comprising:
providing a piezoelectric layer, wherein the piezoelectric layer is positioned between the metamaterial lens layer and the OLED layer.

20. The optical method as claimed in claim 19, further comprising:
applying a control voltage to the piezoelectric layer, wherein a shape of the piezoelectric layer is changed according to the control voltage.
